(19) United States
(12) Patent Application Publication
(10) Pub. No.: US 2026/0338827 A1
(43) Pub. Date: Oct. 29, 2026

(54) Electronic Measuring Device for Measuring Electrical Quantities

(71) Applicant: Robert Bosch GmbH, Stuttgart (DE)

(72) Inventors: Chi Fung Chan, Ostfildern (DE); Jianbang Ying, Hangzhou (CN); Kunal Shyamadas Burman, Echterdingen (DE); Thomas Kohlert, Nerja (ES); Xinhui Zhang, Hangzhou (CN)

(21) Appl. No.: 19/656,063

(22) Filed: Apr. 23, 2026

(30) Foreign Application Priority Data
Apr. 25, 2025 (DE) 10 2025 116 051.1

(51) Int. Cl. G01R 1/04; G01R 15/12; H01M 50/247; H01M 50/271; H01M 50/287; H01M 50/574

(52) U.S. Cl. CPC G01R 1/04; G01R 15/12; H01M 50/247; H01M 50/271; H01M 50/287; H01M 50/574

(57) ABSTRACT

An electronic measuring device for measuring electrical quantities, in particular voltage, current and/or electrical resistance is disclosed. The electronic measuring device includes a housing, in which a battery compartment is configured to accommodate a power source, which is accessible via a removable battery compartment lid. The battery compartment is provided with a disconnect switch which, when the battery compartment lid is removed from the battery compartment, switches off the entire electronic measuring device or at least its control elements.

This application claims priority under 35 U.S.C. § 119 to patent application no. DE 10 2025 116 051.1, filed on Apr. 25, 2025 in Germany, the disclosure of which is incorporated herein by reference in its entirety.

The disclosure relates to an electronic measuring device for measuring electrical quantities, in particular voltage, current, and/or electrical resistances, with a housing, in which a battery compartment is configured to accommodate a power source accessible via a removable battery compartment lid.

### BACKGROUND

CN 220086290 U has as its subject matter a battery cover, as well as a multimeter with such a battery cover. A top battery cover is removed during charging. It is otherwise used to prevent electrical shocks, oil spots, dust, water spots, and the like.

DE 10 2008 036 823 A1 discloses a housing structure with a housing and a corresponding multimeter. The housing has a shell of stiff polymeric material defining at least one groove containing a softer polymeric material. In addition, the housing structure comprises at least one stiff plate element abutting the housing. Among other things, an approach for a sealing arrangement between the battery compartment and the battery compartment lid is disclosed in order to prevent the intrusion of moisture and other contaminants.

DE 10 2005 036 037 A1 relates to a measuring device, in particular to an electro-optical distance measuring device. A housing seal is disclosed, for which a preferably elastic material at least partially encompasses both the housing, which is made of another material, and an opening, such as in particular a battery compartment, and seals it off from the housing interior. As a result, additional sealants or sealing elements can be substantially omitted.

### SUMMARY

According to the disclosure, an electronic measuring device is proposed for measuring electrical quantities, in particular voltage, current, and/or electrical resistances, comprising a housing, in which a battery compartment is configured to accommodate a power source accessible through a removable battery compartment lid. The battery compartment is provided with a disconnect switch which, when the battery compartment lid is removed from the battery compartment, switches off the entire electronic measuring device or at least its control elements.

With the solution proposed according to the disclosure, it can be advantageously achieved that users of the manually operated electronic measuring device are protected from electric shocks.

In an advantageous further development of the electronic measuring device proposed according to the disclosure, it is provided that the battery compartment lid, on an inner side, comprises an actuating element that actuates the disconnect switch when the battery compartment lid is mounted on the battery compartment.

This ensures that, in the mounted state of the battery compartment lid, a proper supply of current and/or voltage is ensured for the electronic measuring device proposed according to the disclosure.

In an advantageous further development of the electronic measuring device proposed according to the disclosure, it is provided that the disconnect switch is recessed into the housing, in particular into a bottom of the battery compartment.

In an advantageous further development of the electronic measuring device, the disconnect switch comprises a switch arm pivotally connected at one end to a switch body. When the battery compartment lid comprising the actuating element is mounted, this switch arm is deflected by the actuating element and contacts a contact provided on the switch body of the disconnect switch to enable the current and/or voltage supply to the electronic measuring device.

In an advantageous further development of the electronic measuring device, it is provided that the disconnect switch is arranged on a top side of a printed circuit board arrangement. Furthermore, in the electronic measuring device proposed according to the disclosure, it is provided that the printed circuit board arrangement in the interior space of the housing is substantially at the level of the bottom of the battery compartment and is biased against a housing rib or a housing projection inside the housing by way of a bias spring.

The electronic measuring device proposed according to the disclosure is further characterized in that, when the battery compartment lid is mounted, its actuating element presses the switch arm of the disconnect switch against a contact point of the switch body and releases the current or voltage supply to the electronic measuring device as well as to its control elements.

Furthermore, in the electronic measuring device proposed according to the disclosure, it is provided that the actuating element on the inner side of the battery compartment lid is substantially rod-shaped or pin-shaped.

In an advantageous embodiment of the electronic measuring device, the actuating element is configured as a spring-loaded contact pin.

Moreover, the electronic measuring device proposed according to the disclosure provides that the power source is configured either as a rechargeable lithium-ion battery or as at least one alkaline battery.

The electronic measuring device proposed according to the disclosure may be a multimeter, a clamp ammeter, a fork ammeter, or a voltage measuring device for measuring electrical quantities, in particular currents, voltages, electrical resistances, capacitances, temperatures, and impedances in DC or AC applications.

The solution proposed according to the disclosure ensures that, in the mounted state of the battery compartment lid on the battery compartment, the disconnect switch arranged in the bottom of the battery compartment within the housing is actuated, and thus a voltage or current supply to the electronic measuring device as well as to its control elements, for example a display or a rotatable selector switch or the like, is ensured. However, once the battery compartment lid is removed from the battery compartment, the rod-shaped or pin-shaped projection, or the projection configured as a spring-loaded contact pin, i.e., the actuating element, on the inside of the battery compartment lid disengages from the disconnect switch. The disconnect switch may also be configured as a magnetic switch or magnetic sensor for shutting down the device when the battery compartment is open. At least the voltage or current supply to the control elements, or the voltage or current supply to the entire electronic measuring device, is thereby switched off so that the occurrence of an electric shock can be safely prevented.

Advantageously, commercially available alkaline batteries in AA or AAA format, or a 9V battery, can be inserted into the electronic measuring device proposed according to the disclosure. As an example, a rechargeable lithium-ion battery or a battery pack consisting of a plurality of rechargeable batteries can also be used as a power source. With regard to the usable power source, a dual power source option is thus possible with the electronic measuring device proposed according to the disclosure. Furthermore, by way of the solution proposed according to the disclosure, improper handling of exposed power sources in the form of batteries can be advantageously prevented, for example if they are recharged when installed in the battery compartment but with the battery compartment lid open. Such a hazardous situation is reliably excluded by the design of the measuring device proposed according to the present disclosure, so that an operator is safely protected from electric shock and other negative effects.

### BRIEF DESCRIPTION OF THE DRAWINGS

Embodiments of the disclosure are described in greater detail hereinafter with reference to the drawings and the subsequent description.

It shows:

FIG. 1 a perspective view of an electronic measuring device,

FIG. 2 a schematic illustration of the electronic measuring device proposed according to the disclosure with a battery compartment lid comprising an actuating element,

FIGS. 3 and 3.1 views of the insides of the housing of the electronic measuring device and the battery compartment lid,

FIGS. 4 and 4.1 top plan perspective views of a battery compartment lid and a battery compartment with alkaline batteries inserted therein, as well as the position of the disconnect switch in the bottom of the battery compartment,

FIG. 5 a schematic illustration of the disconnect switch,

FIG. 6 a section through the housing of the electronic measuring device proposed according to the disclosure, and

FIGS. 7 and 7.1 a representation of the disconnect switch in a tilted position and its installation situation inside the housing of the electronic measuring device with the battery compartment lid closed.

### DETAILED DESCRIPTION

In the following description of the embodiments of the disclosure, identical or similar elements are denoted by identical reference signs, whereby a repeated description of these elements is omitted in individual cases. The drawings show the subject matter of the disclosure only schematically.

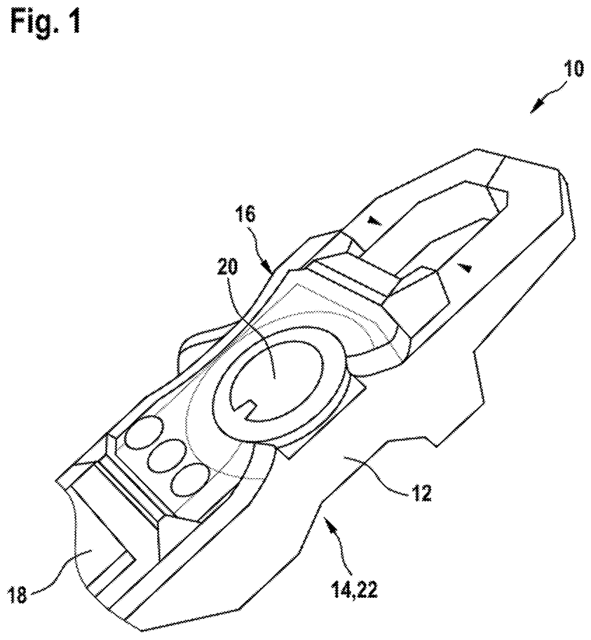

The illustration according to FIG. 1 shows an electronic measuring device 10, which can be configured as a clamp ammeter, for example. This comprises a housing 12, on which legs that are movable relative to one another, shown here only schematically, are accommodated, which legs are in a closed position in the illustration of FIG. 1. On a front side 16 of the housing, there is a rotatable selector switch 20, with which different operating modes of the electronic measuring device 10 can be set. A battery compartment 22, described in more detail in the following figure description, is provided on the rear side 14 of the housing 12 according to the illustration of FIG. 1. This accommodates either commercially available AA, AAA, or 9V alkaline batteries, or a rechargeable lithium-ion battery or battery pack, or the like, for operating the electronic measuring device 10. Furthermore, on the front side 16 of the housing, there is a display for the operator, indicated only in FIG. 1.

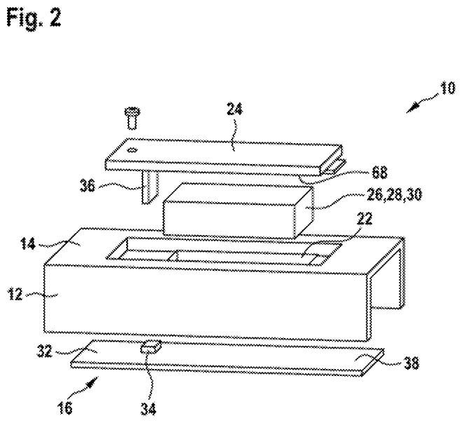

The illustration according to FIG. 2 shows, in a roughly schematic simplification, an electronic measuring device 10, which comprises a housing 12. A battery compartment 22 is located on a rear side 14 of the housing, while a display 18, which is not shown in more detail here, as well as a selector switch 20, configured for example as a rotary knob, can be provided on a front side 16 of the housing for selecting the operating modes of the electronic measuring device 10. The battery compartment 22 serves to accommodate a power source 26 and accommodates commercially available batteries 28, rechargeable batteries 30, a battery pack, or the like.

In the highly simplified exploded view shown in FIG. 2, a power source 26 is inserted into the battery compartment 22 in the housing 12 of the electronic measuring device 10. This may be conventional alkaline batteries 28 (AA, AAA, 9V alkaline batteries), or a rechargeable lithium-ion battery 30 or a battery pack. Thus, the electronic measuring device 10 is suitable for a dual-use application with different power sources 26. As can be seen from the illustration of FIG. 2, an actuating element 36 is formed on an inner side 68 of a battery compartment lid 24. When attached, the battery compartment lid 24 closes the battery compartment 22. In the roughly simplified embodiment according to FIG. 2, the actuating element 36 on the inner side 68 of the battery compartment lid 24 is configured as a rib-shaped projection. The actuating element 36 may also be configured as a spring-loaded contact pin or as a bar-shaped, pin-shaped, or rod-shaped body that extends substantially in a vertical direction from the inner side 68 of the battery compartment lid 24. It is important that, in the mounted state on the battery compartment 22, the head of the actuating element 36 contacts a disconnect switch 34 arranged on a top side 38 of a printed circuit board assembly 32. The disconnect switch 34 is configured such that, when the battery compartment lid 24 is removed from the battery compartment 22, it switches off the entire electronic measuring device 10 or at least its control elements 18, 20.

The housing 12 of the electronic measuring device 10 according to the schematic diagram in FIG. 2 further comprises the aforementioned printed circuit board arrangement 32, on the top side 38 of which the disconnect switch 34 is arranged. The disconnect switch 34 may be installed in the electronic measuring device 10 such that it either disconnects the current or voltage supply of the electronic measuring device 10 or at least disconnects the current or voltage supply of its control elements, such as display 18 or selector switch 20 configured as a rotary knob, from the voltage or current supply.

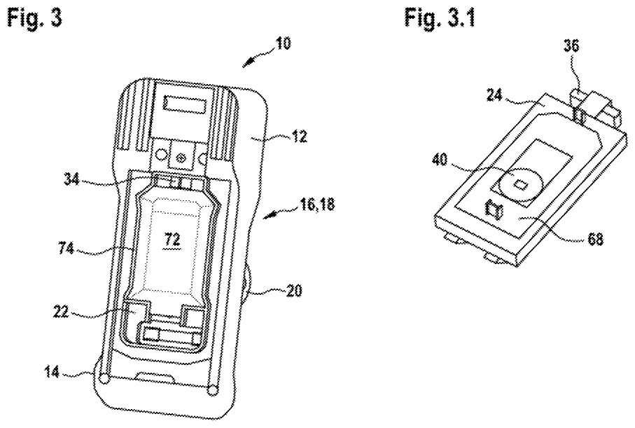

FIGS. 3 and 3.1 show that, when the battery compartment lid 24 is removed, the battery compartment 22 is exposed. The disconnect switch 34 is recessed into the bottom 72 of the battery compartment 22. On the front side 16 of the housing, according to the illustration in FIG. 3, control elements not shown in greater detail are arranged, such as a display 18 and a selector switch 20, configured for example as a rotary knob, with the aid of which different operating modes of the electronic measuring device 10 can be selected. The battery compartment 22 comprises a circumferential battery compartment frame 74, which in terms of its shape and height is configured to be complementary to a likewise circumferential elevation on the inner side 68 of the battery compartment lid 24. Furthermore, the battery compartment lid 24 comprises the aforementioned actuating element 36, which can be configured in a bar-shaped or pin-shaped form and, in the mounted state of the battery compartment lid 24 on the battery compartment 22, actuates the disconnect switch 34 and thus ensures that the voltage or current supply to the electronic measuring device 10 is enabled only when the battery compartment lid 24 is closed. On the inner side 68 of the battery compartment lid 24 is a spacer 40, which, for example, aligns and positions a power source 26 not shown in FIGS. 3 and 3.1, in the form of a lithium-ion rechargeable battery 30 or a battery pack, within the battery compartment.

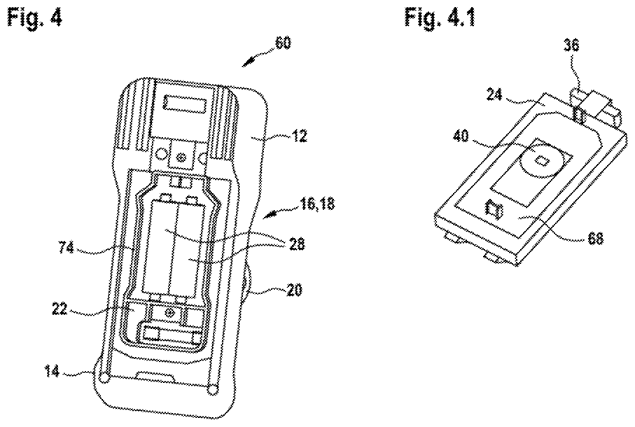

FIGS. 4 and 4.1 show that, instead of a rechargeable lithium-ion battery 30 or a battery pack as the power source 26, commercially available batteries 28, in particular alkaline batteries, can also be used. For example, batteries 28 of sizes AA, AAA, or 6V alkaline batteries are suitable. These are correctly aligned and positioned in the battery compartment 22 on the rear side 14 of the housing 12 of the electronic measuring device 10 with the support of the spacer 40 shown in FIG. 4.1 on the inner side 68 of the battery compartment lid 24. The actuating element 36 can be seen on the inner side 68 of the housing here as well, which actuating element, in the mounted state of the battery compartment lid 24 on the battery compartment 22, actuates the disconnect switch 34, such that only in the mounted state of the battery compartment lid 24 on the battery compartment 22 is the current or voltage supply to the electronic measuring device 10 or to its control elements, such as display 18 and selector switch 20, ensured.

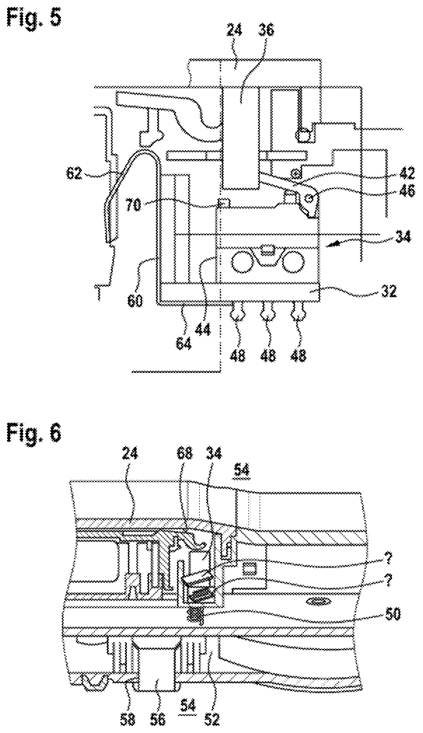

The illustration according to FIG. 5 shows the configuration of the disconnect switch 34 in a highly simplified schematic representation. It is arranged, for example, on a top side 38 of the printed circuit board arrangement 32 by way of a switch body 44. The switch body 44 of the disconnect switch 34 comprises, on its top side, a switch arm 42 pivotable about a joint 46. Below the end of the articulated switch arm 42, a contact point 70 is located on the top side of the switch body 44. From the schematic representation according to FIG. 5, it can be seen that the rod-shaped or bar-shaped actuating element 36, which extends in a vertical direction on the inner side 68 of the battery compartment lid 24, deflects the switch arm 42 about the joint 46 until it contacts the contact point 70. Accordingly, in the contacted state of the contact point 70, i.e., when the battery compartment lid 24 is mounted on the battery compartment 22, the disconnect switch 34 is closed and the voltage or current supply to the electronic measuring device 10 or to its control elements 18, 20 is ensured. Furthermore, a contact spring 60 is provided on the printed circuit board arrangement 32 according to the illustration in FIG. 5, which spring comprises an elastically formed spring tongue 62. For example, the contact spring 60 is secured in a form-fitting or frictional manner along a spring tab 64 on the underside of the printed circuit board assembly 32. Furthermore, a number of contact pins 48 can be seen on the underside of the printed circuit board assembly 32, as shown in FIG. 5. These are contacts for the printed circuit board assembly 32.

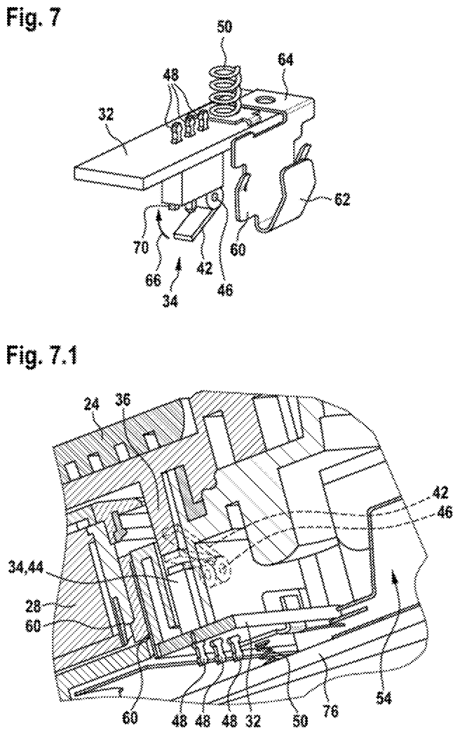

FIG. 6 shows a section through the housing 12 of the electronic measuring device 10, which shows that the printed circuit board assembly 32 is pressed against a housing rib 76 (cf. FIG. 7.1) by way of a bias spring 50. By way of the actuating element 36, as already described in connection with FIG. 5, the disconnect switch 34 is closed as soon as the actuating element 36 deflects the switch arm 42 when the battery compartment cover 24 is mounted on the battery compartment 22, such that the switch arm contacts the contact point 70 of the switch body 44.

It is further apparent from FIG. 6 that an actuating element 56 is inset into a housing wall opening 58. This actuating element 56 may, for example, be arranged laterally on the electronic measuring device 10.

FIGS. 7 and 7.1 show that the printed circuit board assembly 32 shown in FIG. 7 in an inverted position accommodates the switch body 44 of the disconnect switch 34. The switch arm 42 is movable about the joint 46 shown only schematically here, which contacts the contact point 70 provided on the switch body 44 when actuated by the actuating element 36 on the inner side 68 of the battery compartment lid 24, corresponding to a deflection 66. Furthermore, it can be seen from the inverted illustration of FIG. 7 that the contact spring 60, with its spring tab 64, is attached to the underside of the printed circuit board assembly 32, i.e., to the side of the printed circuit board assembly 32 where the contact pins 48 are located. The contact spring 60 further includes an elastically formed spring tongue 62. Preferably, the contact spring 60 is formed as a stamped and bent part made of metallic material. Furthermore, it can be seen from the illustration of FIG. 7 that the printed circuit board assembly 32 is pressed, from the underside—as shown in FIG. 6—by way of the bias spring 50 against a housing rib or a housing projection 76 of the housing 12 of the electronic measuring device 10.

FIG. 7.1 shows the mounted position of the arrangement of FIG. 7 within the interior space 52 of the housing 12 of the electronic measuring device 10. It can also be seen that the printed circuit board assembly 32 is pressed by the bias spring 50 against a housing rib or a housing projection 76. The switch arm 42 shown in FIG. 7.1, which is pivotally connected to the joint 46 of the switch body 44, is pressed against the contact pins 48 on the top side of the switch body 44 by the actuating element 36 extending substantially in the vertical direction. This occurs only when the battery compartment lid 24—as shown in FIG. 7.1—is mounted on the battery compartment 22 and the disconnect switch 34 is closed, thereby enabling the current or voltage supply to the electrical or electronic components of the electronic measuring device 10.

The perspective view according to FIG. 7.1 also shows that, on the underside of the printed circuit board assembly 32, the contact pins 48 extend into the interior space 52 of the housing 12 of the electronic measuring device 10, such that contacting of the printed circuit board assembly 32 is ensured.

The solution proposed according to the disclosure ensures the supply of current or voltage to the electronic measuring device 10 or to its control elements, such as display 18 and selector switch 20, only when the battery compartment cover 24 is mounted on the battery compartment 22. Only in this case does the actuating element 36 on the inner side 68 of the battery compartment lid 24 ensure that the disconnect switch 34 is contacted in the bottom 72 of the battery compartment 22, and that the disconnect switch 34 is closed. Once the battery compartment lid 24 is removed, the disconnect switch 34 opens when the actuating element 36 is no longer present and interrupts the voltage and/or current supply to the electronic measuring device 10 as a whole or at least to its control elements, such as the display 18 and the selector switch 20.

For example, the electronic measuring device 10 according to the figures described above may be configured as a multimeter, a clamp ammeter, a fork ammeter, or a voltmeter, and used for non-contact or contact measurement of electrical quantities, such as currents, voltages, resistances, capacitances, temperatures, impedances, and the like, in DC or AC applications. Furthermore, the electronic measuring device 10 proposed according to the disclosure is suitable for dual use, i.e., the power source 26 used in it can be both conventional batteries 28 (alkaline batteries) and a rechargeable lithium-ion battery 30 or a battery pack.

The disclosure is not limited to the exemplary embodiments described herein and the aspects highlighted thereby. Rather, within the range specified by the claims, a plurality of modifications is possible, which lie within the abilities of a person skilled in the art.

What is claimed is:

1. An electronic measuring device for measuring electrical quantities, comprising:
a housing having a battery compartment configured to accommodate a power source; and
a removable battery compartment lid, wherein the power source is accessible via the removable battery compartment lid,
wherein the battery compartment includes a disconnect switch configured to switch off the entire electronic measuring device or at least control elements of the electronic measuring device when the battery compartment lid is removed from the battery compartment.

2. The electronic measuring device according to claim 1, wherein the battery compartment lid, on an inner side, includes an actuating element configured to acuate the disconnect switch when the battery compartment lid is mounted on the battery compartment.

3. The electronic measuring device according to claim 1, wherein the disconnect switch is recessed into the housing.

4. The electronic measuring device according to claim 1, wherein the disconnect switch includes a switch arm pivotally connected at one end to a switch body.

5. The electronic measuring device according to claim 1, wherein the disconnect switch is accommodated on a top side of a printed circuit board arrangement.

6. The electronic measuring device according to claim 5, wherein the printed circuit board arrangement in the interior space of the housing is substantially at the level of the bottom of the battery compartment and is pressed against a housing rib of the housing by way of a bias spring.

7. The electronic measuring device according to claim 2, wherein:
when the battery compartment lid is mounted, the actuating element is positioned to press the switch arm of the disconnect switch against a contact point of the switch body and enable a current/voltage supply to the electrical measuring device.

8. The electronic measuring device according to claim 1, wherein the actuating element on the inner side of the battery compartment lid is substantially rod-shaped or pin-shaped.

9. The electronic measuring device according to claim 1, wherein the actuating element is configured as a spring-loaded contact pin.

10. The electronic measuring device according to claim 1, wherein the electronic measuring device is configured as a multimeter, a clamp ammeter, a fork ammeter, or a voltmeter for measuring electrical quantities.

11. The electronic measuring device according to claim 1, wherein the electrical quantities are at least one of voltage, current and electrical resistance.

12. The electronic measuring device according to claim 3, wherein the disconnect switch is recessed into a bottom of the battery compartment.

13. The electronic measuring device according to claim 10, wherein the electrical quantities are at least one of currents, voltages, electrical resistances, capacitances, temperatures, and impedances in DC or AC applications.
